(19) United States
(12) Patent Application Publication
(10) Pub. No.: US 2019/0264557 A1
(43) Pub. Date: Aug. 29, 2019

(54) ENCAPSULATED DOWNHOLE ASSEMBLY AND METHOD OF POTTING AND MOUNTING SAME

(71) Applicant: INTELLISERV, LLC, Houston, TX (US)

(72) Inventors: Greg John Perkins, Houston, TX (US); Jeffrey B. Jepson, Houston, TX (US); Alan Dixon Shumway, Houston, TX (US)

(73) Assignee: INTELLISERV, LLC, Houston, TX (US)

(21) Appl. No.: 16/080,103

(22) PCT Filed: Feb. 24, 2017
(86) PCT No.: PCT/US17/19400

§ 371 Date: Aug. 27, 2018

Related U.S. Application Data
(60) Provisional application No. 62/299,862, filed on Feb. 25, 2016.

(51) Int. Cl. E21B 47/12; B65D 73/02; H05K 3/28; H05K 1/02

(52) U.S. Cl. CPC E21B 47/12; B65D 73/02; H05K 2201/2036; H05K 1/0271; H05K 3/284

(57) ABSTRACT

An apparatus for securing a printed wiring assembly (PWA) within an enclosure of a downhole tool includes an elongate base, an elongate cover, and at least one bracket member coupled to the downhole tool. The base is for supporting electrical components that may include electronics, circuitry, conductive strips, and batteries thereon. The cover extends in a longitudinal direction and extends over the central portion of the base. At least one end of the base is uncovered by the cover. The cover includes at least one lateral recess that extends in a direction generally perpendicular to the longitudinal direction. The bracket member has a portion extending into the lateral recess and is configured to engage the cover and secure the cover within the enclosure.

### CROSS-REFERENCE TO RELATED APPLICATIONS

This application claims benefit of U.S. Provisional Application Ser. No. 62/299,862 filed Feb. 25, 2016, and entitled “Encapsulated Downhole Assembly and Method of Potting and Mounting Same,” which is hereby incorporated herein by reference in its entirety.

### BACKGROUND

In drilling a wellbore into the earth, such as for the recovery of hydrocarbons or minerals from a subsurface formation, it is conventional practice to connect a drill bit onto the lower end of a “drill string,” then rotate the drill string so that the drill bit progresses downward into the earth to create the desired borehole. A typical drill string is made up from an assembly of drill pipe sections connected end-to-end, plus a bottom hole assembly (BHA) disposed between the bottom of the drill pipe sections and the drill bit. The BHA is typically made up of sub-components such as drill collars, stabilizers, reamers and/or other drilling tools and accessories, selected to suit the particular requirements of the well being drilled.

Downhole tools may be used in several places along the length of a drill string to receive, amplify, and transmit data signals up and down the drill string using wired drill pipe (WDP). The data link in these tools houses several assemblies including printed wiring assemblies (PWA's) and battery packs. The tools are subjected to extreme pressures and temperatures, as well as vibration, and they may experience sudden impacts and other mechanical stresses. PWA's, battery packs, and other assemblies and devices in the tools may be damaged if not adequately secured in the tool and protected.

### SUMMARY

The problems noted above are addressed by systems and methods for encapsulating, framing, potting, and securing a downhole assembly. In some embodiments, an apparatus for securing a PWA within an enclosure of a downhole tool includes an elongate base, an elongate cover, and at least one bracket member coupled to the downhole tool. The elongate base is configured to support electrical components, such as electronics, circuitry, conductive strips, and batteries thereon. The elongate cover extends in a longitudinal direction and extends over the central portion of the elongate base. In some embodiments, the elongate cover includes a lateral recess adjacent each end of the elongate cover. In some embodiments, the elongate cover includes an outer surface that is arcuate shaped in an end view. At least one end of the elongate base is uncovered by the elongate cover. The elongate cover includes at least one lateral recess that extends in a direction generally perpendicular to the longitudinal direction. The at least one bracket member has a portion extending into the lateral recess. The at least one bracket member is configured to engage the elongate cover and secure the cover within the enclosure. In some embodiments, the apparatus includes two bracket members having portions that extend into the same lateral recess. In some embodiments, the at least on bracket member is arcuate shaped.

Another illustrative embodiment is a frame for a PWA. The frame includes an elongate base, a plurality of standoffs coupled to the base and extending therefrom, and an elongate rail member coupled to the standoffs. The elongate base is configured to support electrical components, including electronics, circuitry, conductive strips, and batteries thereon. In some embodiments, the elongate base includes a plurality of elongate apertures therethrough. The apertures may be arranged in a grid having rows and columns and configured to receive batteries therein. The elongate rail member is supported at a distance D above the elongate base. In some embodiments, the frame further includes a plurality of threaded fasteners extending through the elongate rail member and received in threaded openings in the standoffs. In some embodiments, the frame further includes a first plurality of standoffs disposed on the elongate base in a first row, a second plurality of standoffs disposed on the elongate base in a second row that is generally parallel to the first row, a first rail member coupled to the standoffs of the first row, and a second rail member coupled to the standoffs of the second row. The second rail member is spaced laterally from the first rail member by a distance L.

Yet another illustrative embodiment is a method of potting a PWA. The method includes providing a bottom mold plate. The bottom mold plate includes a PWA-receiving recess, a plurality of standoffs within the recess, and a seal groove disposed around the recess. The method also includes placing a bottom seal plate adjacent a first end of the bottom mold plate, placing an elastomeric seal in the seal groove, placing a PWA in the recess in the bottom mold plate such that the holes in the PWA receive the standoffs, and providing a top mold plate. The top mold plate includes a PWA-receiving recess and at least one port therethrough configured to allow potting material to be injected through the top mold plate. The method also includes placing a top seal plate adjacent a first end of the top mold plate, placing the top mold plate on the bottom mold plate, and injecting potting material into the port.

### BRIEF DESCRIPTION OF THE DRAWINGS

For a detailed description of various examples, reference will now be made to the accompanying drawings in which:

FIG. 1 shows an illustrative downhole tool including an attached, encapsulated assembly in accordance with various embodiments;

FIG. 2 shows an illustrative encapsulated assembly attached to a downhole tool in accordance with various embodiments;

FIG. 3 shows an illustrative top/side view of elongate cover for an encapsulated assembly in accordance with various embodiments;

FIG. 4 shows an illustrative bottom view of an encapsulated assembly in accordance with various embodiments;

FIG. 5 shows an illustrative encapsulated assembly attached to a downhole tool in accordance with various embodiments;

FIG. 6 shows an illustrative mounting bracket for mounting an encapsulated assembly to a downhole tool in accordance with various embodiments;

FIG. 7 shows an illustrative mounting bracket for mounting an encapsulated assembly to a downhole tool in accordance with various embodiments;

FIG. 8 shows an illustrative encapsulated assembly attached to a downhole tool in accordance with various embodiments;

FIG. 9 shows an illustrative mounting bracket for mounting an encapsulated assembly to a downhole tool in accordance with various embodiments;

FIG. 10 shows an illustrative top/side view of an I-beam integrated frame for an encapsulated assembly in accordance with various embodiments;

FIG. 11 shows an illustrative cross-sectional view of an I-beam integrated frame for an encapsulated assembly in accordance with various embodiments;

FIG. 12 shows an illustrative top view of a parallel I-beam integrated frame for an encapsulated assembly in accordance with various embodiments;

FIG. 13 shows an illustrative cross-sectional view of a parallel I-beam integrated frame for an encapsulated assembly in accordance with various embodiments;

FIG. 14 shows an illustrative cross-sectional view of a parallel I-beam integrated frame with recessed batteries for an encapsulated assembly in accordance with various embodiments;

FIG. 15 shows an illustrative bottom mold plate for potting an encapsulated assembly in accordance with various embodiments;

FIG. 16 shows an illustrative top mold plate for potting an encapsulated assembly in accordance with various embodiments; and

FIG. 17 shows an illustrative cross-sectional view of a potting mold assembly for potting an encapsulated assembly in accordance with various embodiments.

### NOTATION AND NOMENCLATURE

In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection, or through an indirect connection via other devices and connections. The recitation “based on” is intended to mean “based at least in part on.” Therefore, if X is based on Y, X may be based on Y and any number of other factors.

### DETAILED DESCRIPTION

The following discussion is directed to various exemplary embodiments of the disclosure. These embodiments should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As discussed above, one or more downhole data link tools may be used in several places along the length of a drill string to receive, amplify, and transmit data signals up and down a drill string. The PWA's, battery packs, and other assemblies and devices utilized to provide the data link may be mounted and secured in place within the downhole tool in such a way as to adequately protect the assembly or device from damage that can be caused by mechanical stresses such as shock and vibration. The amount of space that is available in such a downhole tool for the electronics, battery packs, and other devices is extremely limited.

One conventional system used in downhole tools today to mount an assembly to the downhole tool is the direct-mounted (hard-mount) method. The direct-mounted method typically uses a “perimeter” style frame design that mounts the assembly to the tool pocket/cavity surfaces by compressing the assembly between the frame and the mounting surface utilizing torqued fasteners. Another conventional mounting method is to place the assembly into the tool pocket/cavity and pot the assembly in place using an encapsulant material to hold it in place. Both the direct-mount method and the potting the assembly in place method have many undesirable effects. First, the direct-mount method requires a relatively large frame to adequately secure the assembly in place. This frame uses a large amount of the surface area of the assembly which in turn makes for a more complex assembly design and increases the assembly's overall size. Additionally, the mounting frame interface to the tool pocket/cavity requires a wide interface area in order to mount the frame in place with fasteners. This required area within the pocket/cavity that is needed for the frame to mount, results in an increase in the overall size of the pocket/cavity area. Furthermore, the potting in place mounting method typically uses a large “perimeter” style frame to provide structure to the assembly. The frame uses a large amount of the surface area of the assembly. Additionally, potting the assembly in place within the tool pocket/cavity is a difficult process, and once the assembly is potted in place with encapsulant, the assembly is semi-permanent and is thus, not modular. In other words, once the assembly is potted in place, it is very difficult to remove. In fact, the removal of the assembly often results in damage to the assembly, rendering it unavailable for re-use.

As discussed above, the use of perimeter style frames on downhole assemblies (e.g., a PWA or other electronic board) is common in both the direct-mount method and the potting in place method. This perimeter style frame uses much of the available surface area of the assembly meaning that electronic boards located in the assembly (e.g., PWA) will have to become larger in size to accommodate the frame. Larger and longer length boards are less reliable and take up valuable space in the downhole tool. Additionally, a perimeter style frame is typically high in mass which often correlates with a reduction in reliability under shock and vibration conditions. Furthermore, a perimeter style frame is typically complex to design and expensive to implement.

Thus, there is a need for creating fully and/or partially encapsulated assemblies for downhole data link tools that are easy to install, modular (i.e., easy to remove/replace), and durable (i.e. provides the protection to the assembly from the effects of shock, vibration, and temperature extremes) without requiring a large amount of space. In accordance with various examples, shaped features may be molded into a completed encapsulated assembly. These shaped features may directly interface with a mounting bracket to secure the assembly in place within a downhole tool. The molded bracket interface feature(s) may be mated to one or more brackets to securely mount the assembly within the downhole tool and may provide shock and vibration damping. Thus, a modular mounting system that is easily installable and removable and which may provide mechanical damping from shock and vibration is provided that securely mounts an encapsulated system to the downhole tool. The mounting system may use none of the area on the assembly itself or the downhole tool pocket/cavity, thus, saving valuable space on the tool.

Additionally, the assembly may include a frame in order to provide rigidity to the assembly. This rigidity may provide strength to protect the assembly from flex-caused stress and damage as well as from other forces. The frame may also help to protect against other forces such as shock, vibration, and the effects of temperature. By incorporating an I-beam structure in the frame design, a strong frame is created that provides rigidity for the assembly while utilizing a small amount of the surface area of the assembly. Furthermore, the use of the I-beam structure enables the integration of batteries and other tall or large components that may be mounted on the assembly.

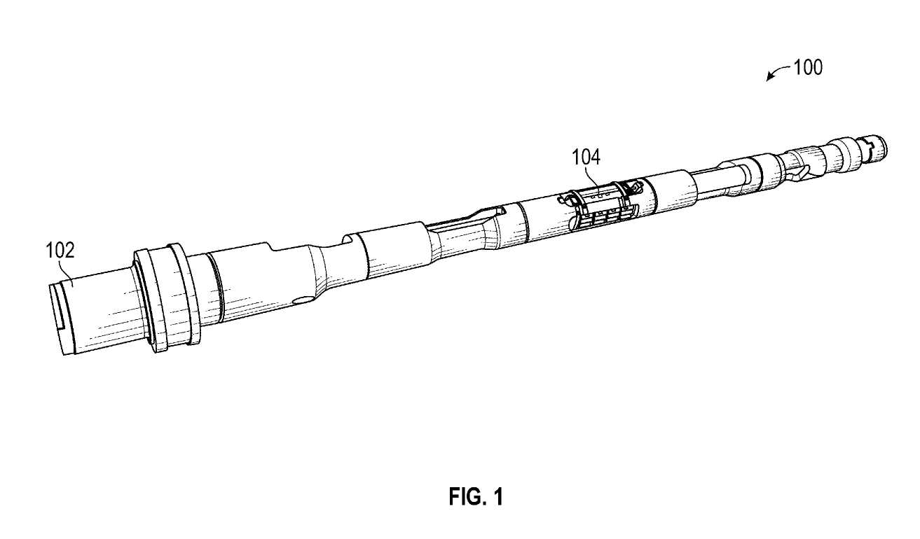

FIG. 1 shows an illustrative downhole tool 100 including an attached, encapsulated assembly 104 in accordance with various embodiments. The downhole tool 100 may be any tool that is configured to function in a downhole environment. For example, the downhole tool 100 may be configured to receive, amplify, and transmit data signals up and down a drill string, in some embodiments, using WDP. Thus, the downhole tool 100 may be a data link tool. The downhole tool 100 includes a structure 102 that includes one or more pockets/cavities. An encapsulated assembly 104 may be placed in a pocket/cavity of the structure 102. The assembly 104 may include electronics, circuitry, conductive strips, and/or batteries so as to effectuate the receiving, amplification, and transmission of data signals up and down the drill string.

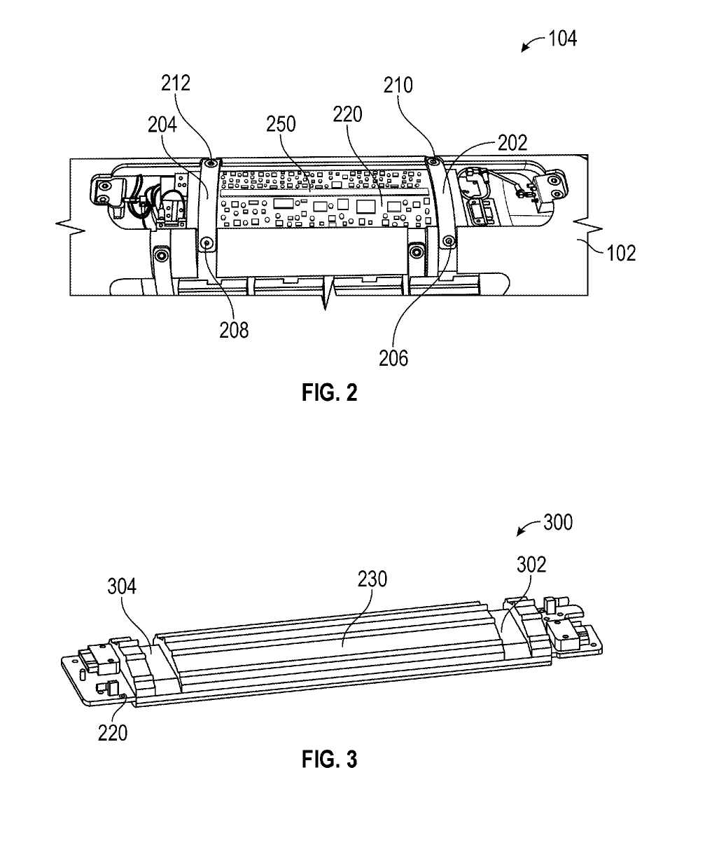

FIG. 2 shows an illustrative encapsulated assembly 104 attached/mounted to downhole tool 100 in accordance with various embodiments. The assembly 104 may be mounted to the downhole tool 100 utilizing mounting brackets 202-204 and fasteners 206-212. The assembly 104 may include an elongate base 220, such as a printed circuit board or any other type of board, and an elongate cover 230. The base 220 may be configured to support the electrical components of the assembly 104. Thus, the base 220 may be configured to support electronics, circuitry, conductive strips, and batteries thereon. The cover 230 extends in a longitudinal direction and extends over the central portion of the base 220. In some embodiments, the cover 230 does not cover the entirety of the base 220. In other words, the cover 230 may leave at least one end of the base 220 uncovered. In some embodiments, by leaving one or both ends of the base 220 uncovered, other electrical connections may be formed between the assembly 104 and the downhole tool 100. In alternative embodiments, the cover 230 may cover the entirety of the base 220.

The fasteners 206-212 may be any type of fastener (e.g., a screw, clip, dowel, nail, bolt, pin, etc.) configured to attach the mounting brackets 202-204 and thus, the assembly 104, to the structure 102. More particularly, the fasteners 206, 210 may be configured to fasten the mounting bracket 202 to the structure 102 while the fasteners 208 and 212 may be configured to fasten the mounting bracket 204 to the structure 102. The assembly 104 may also include an elongate rail member 250 as part of a frame to provide structure and support for the assembly 104.

FIG. 3 shows an illustrative top/side view 300 of elongate cover 230 for encapsulated assembly 104 in accordance with various embodiments. As discussed previously, the cover 230 extends in a longitudinal direction over the central portion of the base 220. The cover 230 may comprise at least one lateral recess 302-304 that extends in a direction generally perpendicular to the longitudinal direction of the cover 230. In some embodiments, the lateral recesses 302-304 may be adjacent each end of the cover 230.

The lateral recesses 302-304 also may be shaped such that a mounting bracket, such as one of mounting brackets 202-204, is capable of extending into each lateral recess. For example, lateral recess 302 may be shaped such that mounting bracket 202 is capable of extending into the lateral recess 302, and lateral recess 304 may be shaped such that the mounting bracket 204 is capable of extending into the lateral recess. The mounting brackets 202-204 then may be fastened to the structure 102 with fasteners 206-212. In some embodiments, the cover 230 includes an outer surface that is arcuate shaped in an end view. Because the outer surface of the cover 230 may be in an arcuate shape from an end view, the lateral recesses 302-304 may also be in an arcuate shape from an end view.

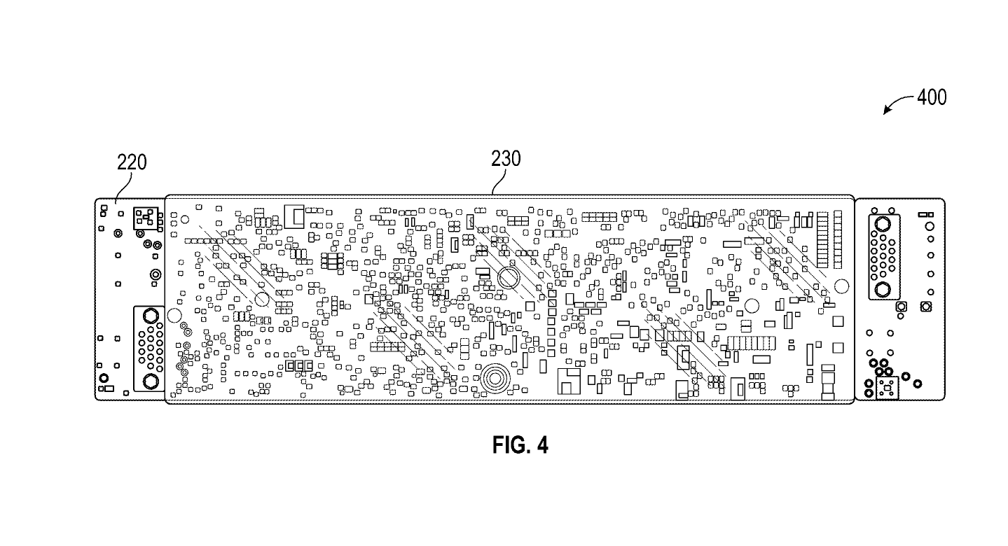

FIG. 4 shows an illustrative bottom view 400 of encapsulated assembly 104 in accordance with various embodiments. As shown from the bottom view 400, the cover 230 of the assembly 104 may cover the bottom side of the base 220. More particularly, the cover 230 may extend in a longitudinal direction under the central portion of the base 220. Thus, in some embodiments, the cover 230 does not cover the entirety of the bottom of the base 220. In other words, the cover 230 may leave at least one end of the bottom of the base 220 uncovered.

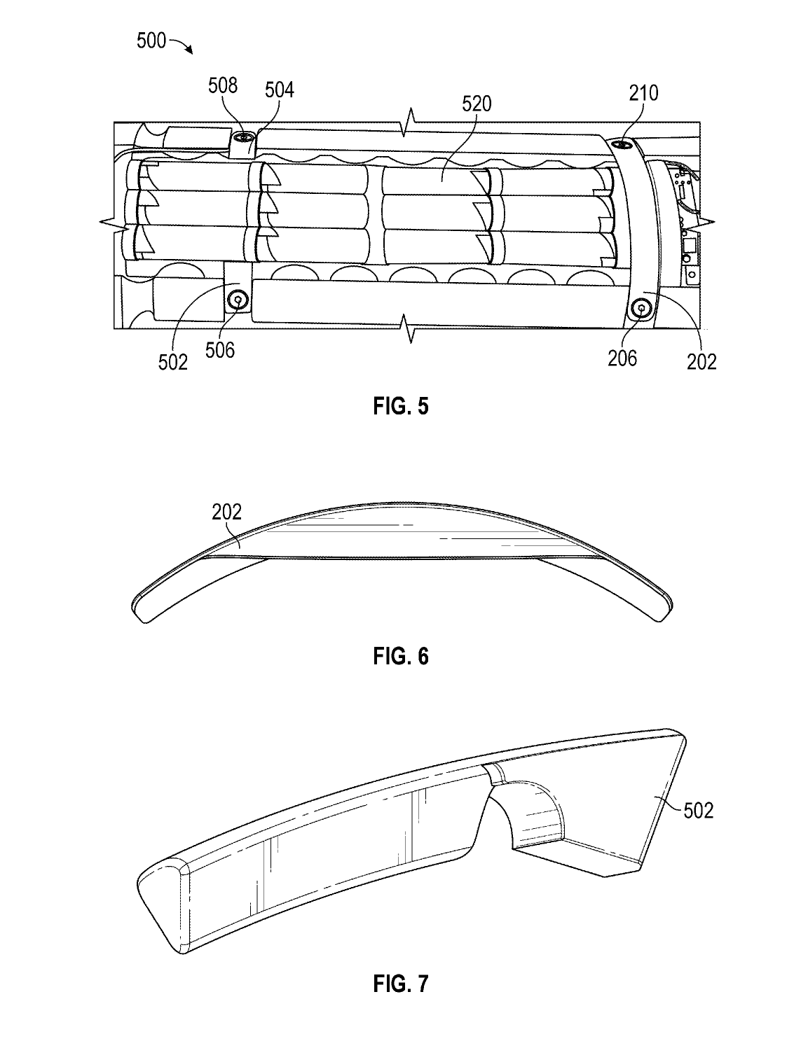

FIG. 5 shows an illustrative encapsulated assembly 500 attached to a downhole tool 100 in accordance with various embodiments. The assembly 500 may be mounted to the downhole tool 100 utilizing mounting brackets 202, 502 and 504 with fasteners 206, 210, 506-508. Similar to the assembly 104, the assembly 500 may include an elongate base and an elongate cover. The base of the assembly 500 may be configured to support the electrical components of the assembly 500. Thus, the base of the assembly 500 may be configured to support electronics, circuitry, conductive strips, and batteries thereon. For example, as shown in FIG. 5, batteries 520 are supported on the base of the assembly 500. The batteries 520 may be configured to provide power to other components and/or assemblies in the downhole tool 100. Thus, the assembly 500 may act as a battery pack. The cover of assembly 500 extends in a longitudinal direction and extends over the central portion of the base of the assembly 500. In some embodiments, the cover of assembly 500 does not cover the entirety of the base of the assembly 500.

Similar to the assembly 104, the cover of the assembly 500 may comprise one or more lateral recesses that extend in a direction perpendicular to the longitudinal direction of the cover. Thus, the mounting bracket 202 may extend into one of the lateral recesses to mount, utilizing fasteners 206 and 210 the assembly 500 to the structure 102. Additionally, in some embodiments, two mounting brackets 502-504 may extend into the same lateral recess to secure, with the fasteners 506-508, the assembly 500 to the structure 102. More particularly, the mounting bracket 502 may extend into a lateral recess of the cover of assembly 500 and fasten, utilizing fastener 506, to the assembly 500 to secure the assembly 500 to the structure 102. Similarly, the mounting bracket 504 may extend into a lateral recess of the cover of assembly 500 and fasten, utilizing fastener 508, to the assembly 500 to secure the assembly 500 to the structure 102. The fasteners 506-508, like fasteners 206-212, may be any type of fastener (e.g., a screw, clip, dowel, nail, bolt, pin, etc.) configured to attach the mounting brackets 502-504 and thus, the assembly 500, to the structure 102. Mounting brackets 502-504 may, in some embodiments, be utilized where the height of the assembly 500 does not allow a mounting bracket to span across the entire assembly 500. For example, if the height of assembly 500 prevents the use of mounting bracket 202 or 204, the combination of mounting brackets 502 and 504 may be utilized instead to secure the assembly 500 to the structure 102.

FIG. 6 shows an illustrative mounting bracket 202 for mounting encapsulated assembly 104 and/or 500 to downhole tool 100 in accordance with various embodiments. The mounting bracket 202 may be arcuate in shape (e.g., a top surface of the mounting bracket 202 may be arcuate in shape to match the shape of the top surface of the cover of the assembly 104 and/or 500) and designed to fit into a lateral recess in the cover of the assembly 104 and/or 500. For example, a bottom surface of the mounting bracket 202 may be configured to couple with the top surface of the lateral recess 302 while the top surface of the mounting bracket 202 may be flush with the remaining sections of the cover 230. In some embodiments, the mounting bracket 202 is constructed of a metal (e.g., aluminum, steel, brass, etc.). In other embodiments, the mounting bracket 202 is constructed of a plastic material or any other material or combination of materials. Mounting bracket 204 may be similar in shape and construction as mounting bracket 202.

FIG. 7 shows an illustrative mounting bracket 502 for mounting encapsulated assembly 500 to downhole tool 100 in accordance with various embodiments. The mounting bracket 502 may be arcuate in shape (e.g., a top surface of the mounting bracket 702 may be arcuate in shape to match the shape of the top surface of the cover of the assembly 500) and designed to fit into a lateral recess in the cover of the assembly 500. For example, a bottom surface of the mounting bracket 502 may be configured to couple with the top surface of the lateral recess 304 while the top surface of the mounting bracket 502 may be flush with the remaining sections of the cover 230. The top surface of the mounting bracket 502 may be configured to extend from the edge of the assembly 500 along the lateral recess 304 for some length that is, in some embodiments, less than half of the length of the lateral recess 304. In some embodiments, the mounting bracket 502 is constructed of a metal (e.g., aluminum, steel, brass, etc.). In other embodiments, the mounting bracket 502 is constructed of a plastic material or any other material or combination of materials. Mounting bracket 504 may be similar in shape and construction as mounting bracket 502. In this way, the two mounting brackets 502 and 504 may extend into the same lateral recess, lateral recess 304, to engage and secure the cover of the assembly 500 to the structure 102.

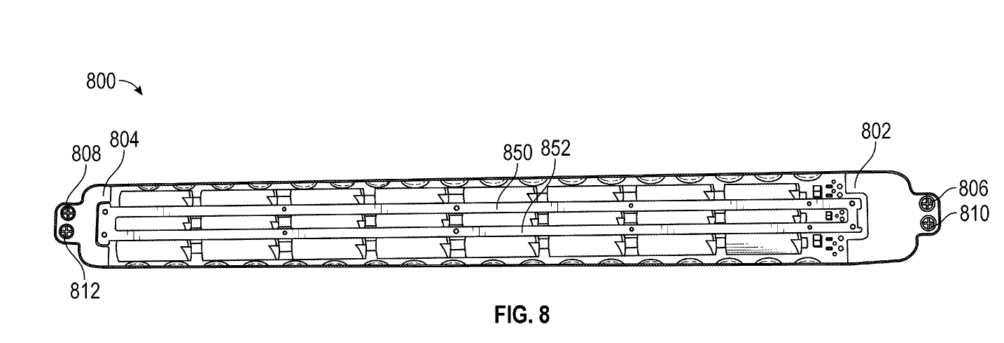

FIG. 8 shows an illustrative encapsulated assembly 800 attached to downhole tool 100 in accordance with various embodiments. The assembly 800 may be mounted to the downhole tool 100 utilizing mounting brackets 802-804 with fasteners 806-812. Similar to the assemblies 104 and 500, the assembly 800 may include an elongate base and an elongate cover. The base of the assembly 800 may be configured to support the electrical components of the assembly 800. Thus, the base of the assembly 800 may be configured to support electronics, circuitry, conductive strips, and batteries thereon. For example, as shown in FIG. 8, batteries are supported on the base of the assembly 800. The batteries may be configured to provide power to other components and/or assemblies in the downhole tool 100. Thus, the assembly 800 may act as a battery pack. The cover of assembly 800 extends in a longitudinal direction and may extend over the entirety of the base of the assembly 800.

Unlike the assemblies 104 and 500, the cover of the assembly 800 does not comprise one or more lateral recesses that extend in a direction perpendicular to the longitudinal direction of the cover. Instead, in this exemplary embodiment, the mounting brackets 802-804 are located at each longitudinal end of the cover of the assembly 800. More particularly, mounting bracket 802 may couple with the cover of the assembly 800 and fasten, utilizing fasteners 806 and 810, the assembly 800 to the structure 102. Similarly, the mounting bracket 804 may couple with the cover of the assembly 800 and fasten, utilizing fasteners 808 and 812, the assembly 800 to the structure 102. The fasteners 806-812, like fasteners 206-212 and 504-506, may be any type of fastener (e.g., a screw, clip, dowel, nail, bolt, pin, etc.) configured to attach the mounting brackets 802-804 and thus, the assembly 800, to the structure 102. The assembly 800 may also include elongate rail members 850-852 as part of a frame to provide structure and support for the assembly 800.

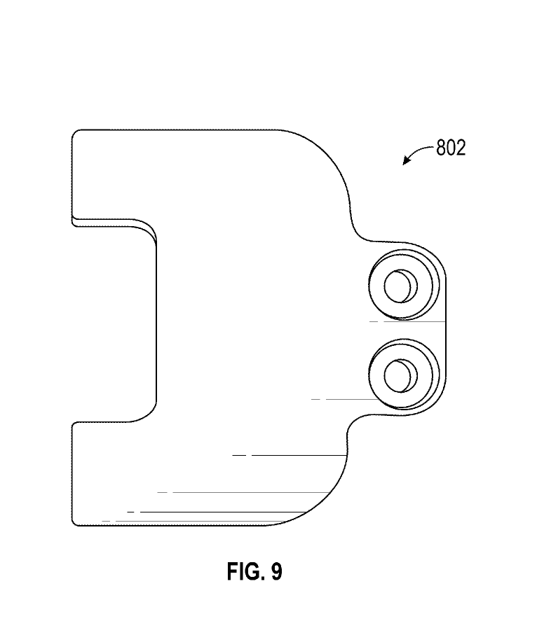

FIG. 9 shows an illustrative mounting bracket 802 for mounting encapsulated assembly 800 to downhole tool 100 in accordance with various embodiments. The mounting bracket 802 may be arcuate in shape (e.g., a top surface of the mounting bracket 802 may be arcuate in shape to match the shape of the top surface of the cover of the assembly 800) and designed to couple to the cover of the assembly 800 at one of the cover's longitudinal ends. The top surface of the mounting bracket 802 may be flush with the remaining sections of the cover of the assembly 800. In some embodiments, the mounting bracket 802 is constructed of a metal (e.g., aluminum, steel, brass, etc.). In other embodiments, the mounting bracket 802 is constructed of a plastic material or any other material or combination of materials. Mounting bracket 804 may be similar in shape and construction as mounting bracket 802.

Thus, features may be shaped (molded) in to a completed encapsulated assembly, such as assemblies 104, 500, and/or 800, that can then interface with the mounting brackets, such as mounting brackets 202-204, 502-504, and/or 802-804, that are used to secure the assembly within the downhole tool. The molded bracket interface features are mated to the brackets which securely mounts the assembly within the downhole tool. Therefore, fully and partially encapsulated assemblies, such as assemblies 104, 500, and/or 800, are mounted in such a way that there is not any “hard-mounting” or direct contact made between the assembly structure itself and the mounting surfaces of the tool pocket/cavity area. The encapsulant material (i.e. potting material) that surrounds the assembly and/or battery pack that makes up the cover of the assembly is the only material that makes contact with the tool pocket/cavity surfaces and also to the mounting bracket. This allows for the surrounding encapsulant material to protect and to provide support to the assembly within the tool pocket/cavity.

Furthermore, due to the design of the cover, the mounting brackets, and fasteners provide a modular mounting system in which an encapsulated assembly can be securely mounted and easily installed and removed. Such designs use none of the area of the assembly itself allowing for little or no interference from the mounting design to occur on the assembly, thus making a simpler assembly design that is smaller in size. Additionally, such mounting designs use none of the area in the tool pocket/cavity allowing for little or no interference from the mounting design to occur in the pocket/cavity area, thus making a simpler pocket/cavity design that is 100% available for the assembly itself. Moreover, the amount of shock and vibration damping can be altered by changing the shape of the molded bracket interface features, the shape of the bracket, and the encapsulant type.

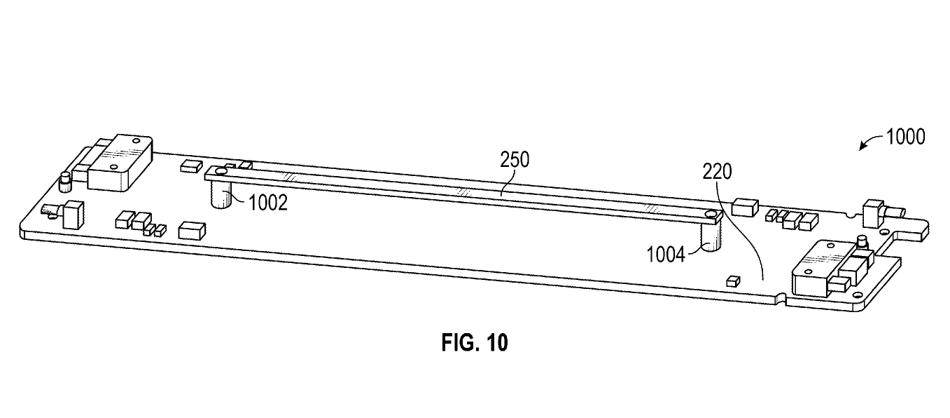

FIG. 10 shows an illustrative top/side view 1000 of an I-beam integrated frame for an encapsulated assembly in accordance with various embodiments. As discussed above, an elongate rail member 250 of an assembly, such as assemblies 104, 500, and/or 800, may form a part of a frame to provide rigidity to the base 220 and the remaining structures of the assembly. Thus, the assembly may include standoffs 1002-1004, which in some embodiments may be cylindrical in shape to support the rail member 250. The standoffs 1002-1004 are coupled to the base, utilizing any coupling means, and extend therefrom. The rail member 250 is coupled to the standoffs, utilizing any coupling means, and supported above the base 220. In some embodiments, a threaded fastener extends through the rail member 250 and received in a threaded opening of one of the standoffs 1002-1004. In some embodiments, one standoff is located at each longitudinal end of the rail member 250. Thus, standoff 1002 may be located at one longitudinal end of rail member 250 while standoff 1004 may be located at the other longitudinal end of rail member 250. The rail member 250 may be constructed of a metal (e.g., aluminum, steel, brass, etc.). In other embodiments, the rail member 250 is constructed of a plastic material or any other material or combination of materials.

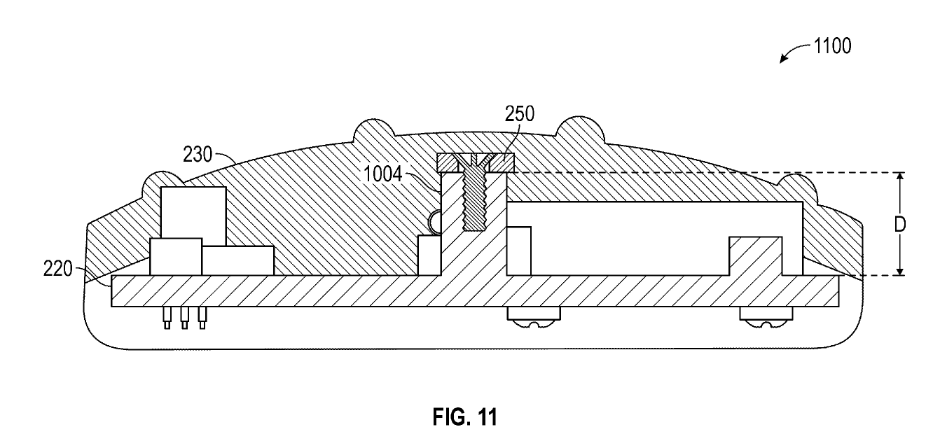

FIG. 11 shows an illustrative cross-sectional view 1100 of an I-beam integrated frame for an encapsulated assembly in accordance with various embodiments. As shown in the cross-sectional view 1100, the standoff 1004 is coupled to the rail member 250 to support the rail member 250 at a distance D above the base. The distance D may be any distance, and in some embodiments, is a distance that provides maximum or close to maximum (e.g., within 5% of maximum) rigidity to the base 220 and/or the assembly itself. In other embodiments, the distance D may be based on the height of the components coupled to base 220. For example, if the highest component coupled to the base 220 is 10 cm above the base 220, then the distance D may be 15 cm. Thus, the distance D may be greater than or equal to the highest component of the assembly coupled to the base 220. In alternative embodiments, the distance D may be recessed in between taller components, such as batteries, providing a very low profile for the frame. The cover 308 then covers and encapsulates the components, including the electrical components, standoffs 1002-1004, and rail member 250 that are supported by the base 220.

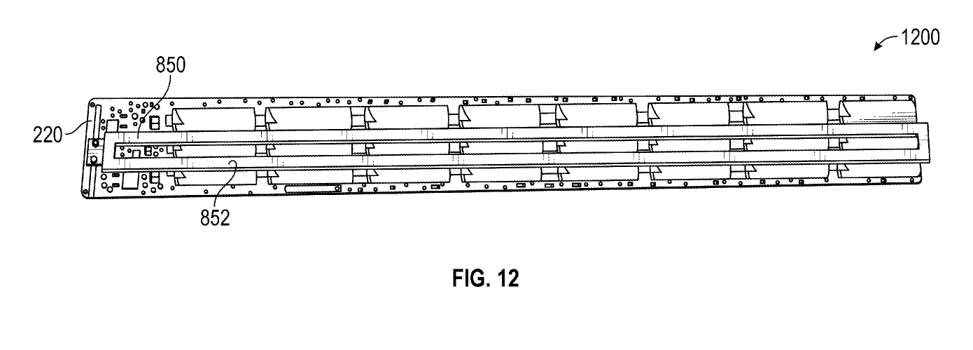

FIG. 12 shows an illustrative top view 1200 of a parallel I-beam integrated frame for an encapsulated assembly in accordance with various embodiments. As discussed above, in some embodiments, more than one rail member, such as rail members 850-852 of an assembly, such as assemblies 104, 500, and/or 800, may form a part of a frame to provide rigidity to the base 220 and the remaining structures of the assembly. While not shown in FIG. 12, the assembly may include four standoffs, each standoff located at the longitudinal end of a rail member. For example, a standoff may be coupled to the base 220 and rail member 850 at each longitudinal end of rail member 850. Additionally, a standoff may be coupled to the base 220 and rail member 852 at each longitudinal end of rail member 852. In other words, the frame may include two or more standoffs disposed on the base 220 in a first row, two or more standoffs disposed on the base 220 in a second row that is generally parallel to the first row, a rail member 850 coupled to the standoffs of the first row, and rail member 852 coupled to the standoffs in the second row. In some embodiments, the rail members 850-852 are coupled to one another with a connector at each longitudinal end of the rail members 850-852. The rail members 850-852 and connector may be constructed of a metal (e.g., aluminum, steel, brass, etc.). In other embodiments, the rail member s 850-852 and connector are constructed of a plastic material or any other material or combination of materials.

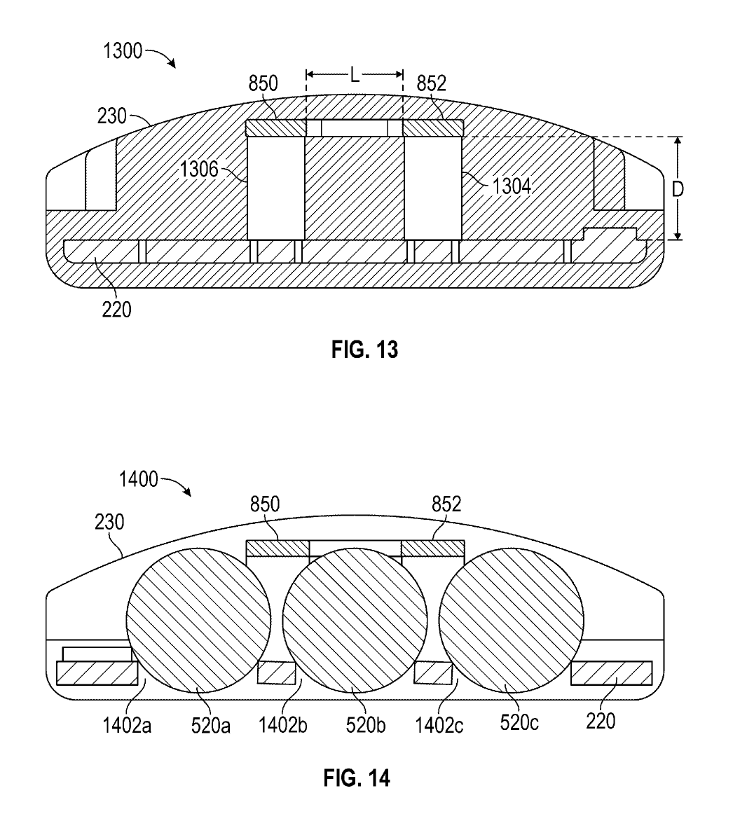

FIG. 13 shows an illustrative cross-sectional view 1300 of a parallel I-beam integrated frame for an encapsulated assembly in accordance with various embodiments. As shown in the cross-sectional view 1300, the assembly may include standoffs 1304-1306, which in some embodiments may be cylindrical in shape to support the rail members 850-852. The standoffs 1304-1306 are coupled to the base 220, utilizing any coupling means, and extend therefrom. The rail member 850 is coupled to standoff 1306, utilizing any coupling means, and supported above the base 220 at a distance D above the base 220. The rail member 852 is coupled to standoff 1304, utilizing any coupling means, and supported above the base 220 at a distance D above the base 220. In some embodiments, a threaded fastener extends through the rail members 850-852 and received in a threaded opening in one of the standoffs 1304-1306. The distance D may be any distance, and in some embodiments, is a distance that provides maximum or close to maximum (e.g., within 5% of maximum) rigidity to the base 220 and/or the assembly itself. In other embodiments, the distance D may be based on the height of the components coupled to base 220. For example, if the highest component coupled to the base 220 is 10 cm above the base 220, then the distance D may be 15 cm. Thus, the distance D may be greater than or equal to the highest component of the assembly coupled to the base 220. In alternative embodiments, the distance D may be recessed in between taller components, such as batteries, providing a very low profile for the frame. The cover 308 then covers and encapsulates the components, including the electrical components, standoffs 1304-1306, and rail members 850-852 that are supported by the base 220. The rail member 850 is spaced laterally from the rail member 852 by a distance L. The distance L may be any distance, and in some embodiments, is a distance that provides maximum or close to maximum (e.g., within 5% of maximum) rigidity to the base 220 and/or the assembly itself.

FIG. 14 shows an illustrative cross-sectional view 1400 of a parallel I-beam integrated frame with recessed batteries 520a-c for an encapsulated assembly in accordance with various embodiments. As shown in the cross-sectional view 1400, the base 220 may include a number of apertures, including apertures 1402a-c, therethrough. The apertures may be arranged in a grid having rows and columns. Thus, the apertures 1402a-c make up one row of the grid along a generally perpendicular to the longitudinal direction of the base 220. Additional columns of the grid may be located along the longitudinal direction of the base 220 from the apertures 1402a-c. Thus, a fourth aperture, may be located in a longitudinal direction along the base 220 from the aperture 1402a, a fifth aperture may be located in a longitudinal direction along the base 220 from the aperture 1402b, and a sixth aperture may be located in a longitudinal direction along the base 220 from the aperture 1402c. The fourth, fifth, and sixth apertures may be configured in a row in a generally perpendicular direction to the longitudinal direction of the base 220.

The apertures, including apertures 1402a-c, may be configured to receive batteries therein. In other words, batteries 520a-c may be configured to be received by the apertures 1402a-c. More particularly, battery 520a may be configured to be received in the aperture 1402a, the battery 520b may be configured to be received in the aperture 1402b, and battery 520c may be configured to be received in aperture 1402c. As shown in FIG. 14, the rail members 850-852 may be recessed between the columns of batteries, including batteries 520a-c, so that the frame provides a low profile.

The I-beam structure of the frame shown in the FIGS. 10-14 may be comprised of the base 220, which may be made of PWB, the standoffs described above, and the rail members described above. The combination of the assembly base 220, such as a PWB, and the other frame materials that are connected and held up above the base 220 (i.e., the standoffs and rail members) creates the complete I-beam structure. By utilizing I-beam structural properties to create the frame rigidity, a high degree of strength using a minimal amount of material is provided to the assembly. Because the frame may be recessed in between taller components, such as batteries, the frame may provide a low profile such that the frame may be utilized in places where a conventional perimeter style frame may not be used. Additionally, the total surface area for mounting the described I-beam frames is greatly reduced compared to conventional perimeter style frames, thus, allowing for smaller overall assembly size, a simpler design, a less expensive design, and reduced mass providing better reliability of the assembly under shock and vibration.

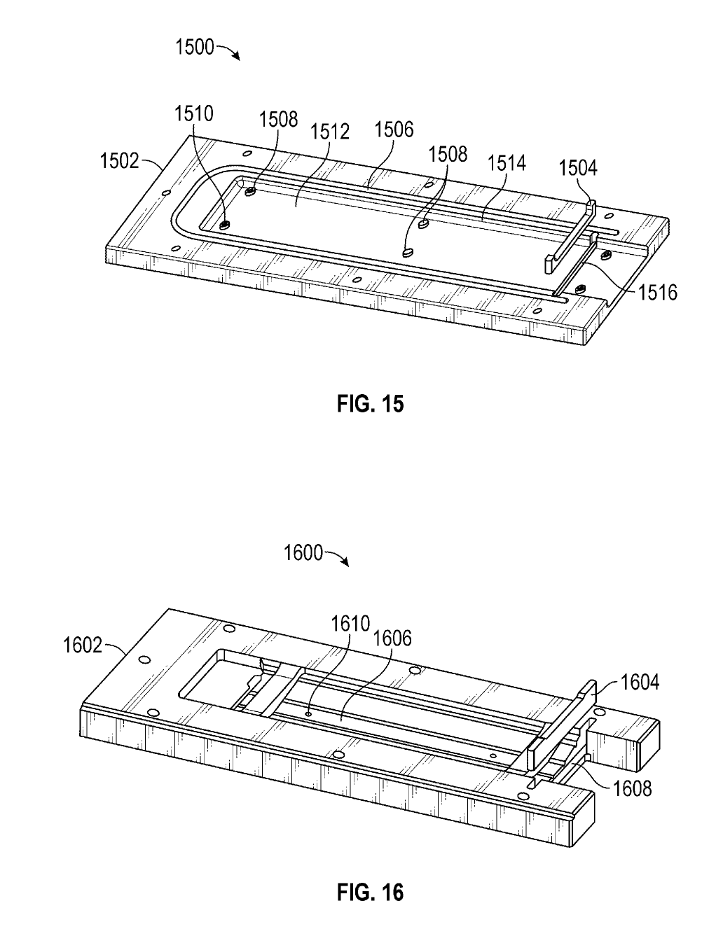

To create the cover, such as cover 230, of an assembly, such as assemblies 104, 500, and 800, the frame, the base 220, and the components coupled to the base 220 may be potted. However, potting material is applied as a liquid, therefore it can be a challenge to contain the potting material to desired locations (e.g., to create the cover described above). FIG. 15 shows an illustrative bottom mold plate 1500 for potting an encapsulated assembly in accordance with various embodiments. FIG. 16 shows an illustrative top mold plate 1600 for potting an encapsulated assembly in accordance with various embodiments. The bottom mold plate 1500 may include a base 1502, a lower seal plate 1504, a lower plate groove 1516, an elastomeric seal 1506 (e.g., an O-ring), a board receiving recess 1512, a seal groove 1514 disposed around the recess 1512, a locating pin and standoff 1510 within the recess 1512, and one or more additional standoffs 1508 within the recess 1512. The top mold plate 1600 may include a base 1602, an upper seal plate 1604, an upper plate groove 1608, a board receiving recess 1606, and a port 1610 to allow potting material to be injected through the base 1602 into the board receiving recess 1606. While shown as being located in the top mold plate 1600, the port 1610 may, in alternative embodiments, be located in the bottom mold plate 1500.

In some embodiments, prior to potting, at least the base 1502 of the bottom mold plate 1500 and the base 1602 of the top mold plate 1600 are coated with a permanent mold-release coating (e.g., nickel Teflon coating). The upper plate 1604 and the lower plate 1504 are designed to create a stop for the potting material while also sealing against the elastomeric seal 1506. In some embodiments, the surface of the plates 1504 and 1604 are slightly concave to help center the elastomeric seal 1506 during assembly of the entire mold. An adhesive may be utilized to fix the lower plate 1504 into lower plate groove 1516 adjacent a first end of the bottom mold plate 1500 and the upper plate 1604 into upper plate groove 1608 adjacent a first end of the top mold plate 1600. The adhesive may also seal around the areas that the lower seal plate 1504 and the upper seal plate 1604 make contact with the plate grooves 1516 and 1608 surfaces. The adhesive may be compatible with the curing temperature of the potting material.

The locating pin 1510 and the standoffs 1508 allow for the base 220 (e.g., a PWA) to be located correctly in the mold. More particularly, the base 220 (e.g., PWA) may have holes that are configured to receive the locating pin 1510 and standoffs 1508. The locating pin 1510 and standoffs 1508 may be positioned within the recess 1512. Thus, when these holes of the base 220 receive the locating pin 1510 and standoffs 1508, the base 220 is correctly positioned within the mold. The elastomeric seal 1506 may be placed in the seal groove 1514.

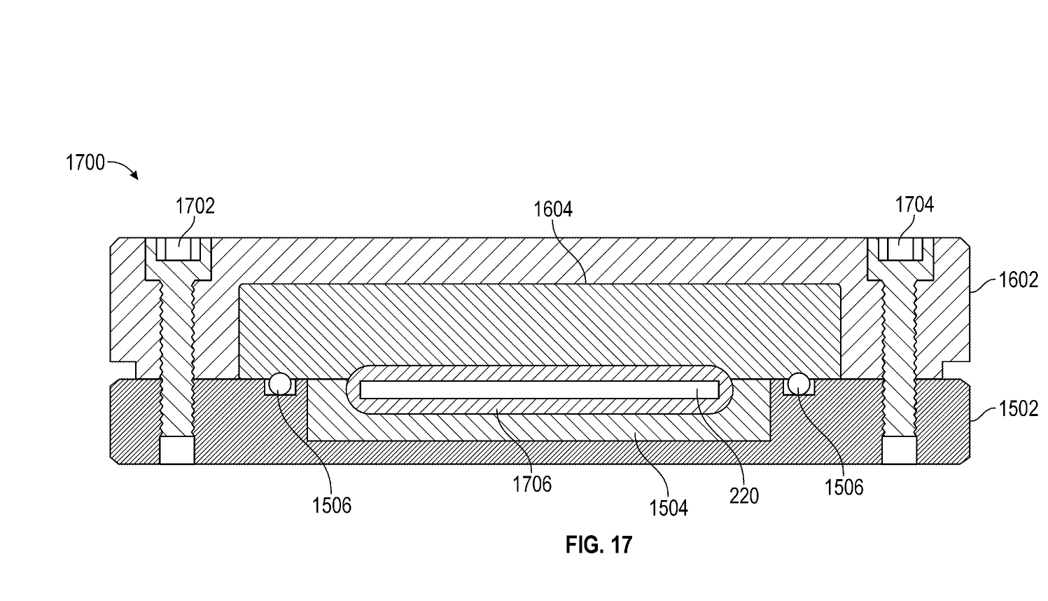

FIG. 17 shows an illustrative cross-sectional view of a potting mold assembly 1700 for potting an encapsulated assembly in accordance with various embodiments. More particularly, the potting mold assembly 1700 comprises the top mold plate 1600 being coupled with the bottom mold plate 1500. In other words, the top mold plate 1600 may be placed on top of the bottom mold plate 1500. The base 220 (e.g., PWA) may be placed in the recess 1512. In some embodiments, a small amount of high viscosity silicone sealant may be applied at the seal round the base 220 (location 1706). The mold plates 1600 and 1700 then may be fastened together utilizing fasteners 1702-1704 which may be any type of fastener (e.g., (e.g., a screw, clip, dowel, nail, bolt, pin, etc.). In some embodiments, the potting mold assembly 1700 is placed in a vertical position, such that the seal plates 1504 and 1604 are located at the bottom of the assembly 1700. The potting material then may be injected into the port to create the cover 230.

The above discussion is meant to be illustrative of the principles and various embodiments of the present invention, which is defined by the claims below. Numerous variations and modifications will become apparent to those skilled in the art once the above disclosure is fully appreciated. It is intended that the following claims be interpreted to embrace all such variations and modifications.

1. An apparatus for securing a printed wiring assembly (PWA) within an enclosure of a downhole tool, comprising:
an elongate base for supporting electrical components thereon;
an elongate cover extending in a longitudinal direction and extending over the central portion of the elongate base, at least one end of the base being uncovered by the cover;
wherein the cover comprises at least one lateral recess that extends in a direction generally perpendicular to the longitudinal direction; and
at least one bracket member coupled to the downhole tool and having a portion extending into the lateral recess, the bracket member being configured to engage the cover and secure the cover to the enclosure.

2. The apparatus of claim 1 further comprising two bracket members having portions extending into the same lateral recess.

3. The apparatus of claim 1 wherein the bracket member is arcuate shaped.

4. The apparatus of claim 1 wherein the cover comprises a lateral recess adjacent each end of the cover and wherein the cover comprises an outer surface that is arcuate shaped in an end view.

5. The apparatus of claim 1 further comprising a frame for the PWA within the enclosure, the frame including:
a plurality of standoffs coupled to the base and extending therefrom; and
an elongate rail member coupled to the standoffs and supported at a distance D above the base.

6. The apparatus of claim 5 wherein the frame further includes a plurality of threaded fasteners extending through said rail and received in threaded openings in the standoffs.

7. The apparatus of claim 5 wherein the frame further includes:
a first plurality of standoffs disposed on the base in a first row;
a second plurality of standoffs disposed on the base in a second row that is generally parallel to the first row;
a first rail member coupled to the standoffs of the first row; and
a second rail member coupled to the standoffs of the second row, the second rail member being spaced laterally from the first rail member by a distance L.

8. The apparatus of claim 5 wherein the base comprises a plurality of elongate apertures therethrough, the apertures arranged in a grid having rows and columns and configured to receive batteries therein.

9. The apparatus of claim 1 wherein the PWA is configured to be potted.

10. A frame for a printed wiring assembly (PWA) comprising:
an elongate base for supporting electrical components thereon;
a plurality of standoffs coupled to the base and extending therefrom; and
an elongate rail member coupled to the standoffs and supported at a distance D above the base.

11. The frame of claim 10 further comprising a plurality of threaded fasteners extending through said rail and received in threaded openings in the standoffs.

12. The frame of claim 10 further comprising:
a first plurality of standoffs disposed on the base in a first row;
a second plurality of standoffs disposed on the base in a second row that is generally parallel to the first row;
a first rail member coupled to the standoffs of the first row; and
a second rail member coupled to the standoffs of the second row, the second rail member being spaced laterally from the first rail member by a distance L.

13. The frame of claim 10 wherein the base comprises a plurality of elongate apertures therethrough, the apertures arranged in a grid having rows and columns and configured to receive batteries therein.

14. A method of potting a printed wiring assembly (PWA), comprising:
providing a bottom mold plate, the bottom mold plate comprising a PWA-receiving recess, a plurality of standoffs within the recess, and a seal groove disposed around the recess;
placing a bottom seal plate adjacent a first end of the bottom mold plate;
placing an elastomeric seal in the seal groove;
placing a PWA in the recess in the bottom mold plate such that the holes in the PWA receive the standoffs;
providing a top mold plate, the top mold plate comprising a PWA-receiving recess, and at least one port therethrough configured to allow potting material to be injected through the top mold plate;
placing a top seal plate adjacent a first end of the top mold plate;
placing the top mold plate on the bottom mold plate;
injecting potting material into the port.
